(19) United States
(12) Patent Application Publication
(10) Pub. No.: US 2026/0318983 A1
(43) Pub. Date: Oct. 15, 2026

(54) IN-SITU CIRCUIT BOARD INTERCONNECT TESTING SYSTEM

(71) Applicant: NVIDIA CORPORATION, Santa Clara, CA (US)

(72) Inventors: Sean Xiong CHEN, Portland, OR (US); Jinshui LIU, Plano, TX (US); Astitwa Sarthak LATHE, San Jose, CA (US)

(21) Appl. No.: 19/262,999

(22) Filed: Jul. 8, 2025

Related U.S. Application Data
(60) Provisional application No. 63/786,192, filed on Apr. 9, 2025.

(51) Int. Cl. G01R 31/28

(52) U.S. Cl. CPC G01R 31/2813; G01R 31/2806

(57) ABSTRACT

In one embodiment, a diagnostic instrument includes a first test blade coupled to a first slot in a rack, and a second test blade coupled to a second slot in the rack, where the first slot and the second slot are coupled together via a first interconnect. The diagnostic instrument further includes a test module that performs an in-system end-to-end signal integrity test of the first interconnect by transmitting a first test signal across the first interconnect via the first test blade, receiving a second test signal from across the first interconnect via the second test blade, and generating an analysis of the first interconnect based on the first test signal and the second test signal. In another embodiment, the diagnostic instrument includes the first blade and the test module. The disclosed techniques can be implemented in manufacturing floors, data centers, and other environments where server racks are deployed.

### CROSS-REFERENCE TO RELATED APPLICATIONS

This application claims the benefit of U.S. Provisional Application titled “TECHNIQUES FOR TESTING DATA CENTER RACK-SCALE HIGH-SPEED INTERCONNECTS,” filed on Apr. 9, 2025, and having Ser. No. 63/786,192. The subject matter of this related application is hereby incorporated herein by reference.

### BACKGROUND

### Field of the Various Embodiments

Embodiments of the present disclosure relate generally to data centers and cloud computing environments, manufacturing floors, and more specifically to an in-situ circuit board interconnect Time Domain Reflectometry (TDR), or Vector Network Analysis (VNA), or Bit Error Rate (BER) testing system, or any system that performs a Signal Integrity (SI) performance test.

A rack in a typical data center includes an array of slots where blades can be mounted, as well as a backplane that interconnects the different slots. A given blade is a modular computer system, or a network, or storage device, that can slide into a given slot in the rack. Connectors on the blade then couple with connectors on the backplane, providing the blade with access to other blades in the rack. Under certain conditions, interconnects within the backplane can experience failures of bad connectivity and/or high error rates beyond limits between the various slots. A conventional approach to evaluating these kinds of backplane issues involves removing all blades and the backplane from the rack and then connecting the backplane to testing equipment. This approach requires technical skill, a significant time commitment, and expensive testing equipment. In addition, the failures could be due to connections on the blades.

As the foregoing illustrates, what is needed in the art is a more effective technique for diagnosing interconnect failures in racks that reside at manufacturing floor or in data centers.

### GENERAL DESCRIPTION

In one embodiment, a diagnostic instrument comprises a first test blade coupled to a first slot in a rack, and a second test blade coupled to a second slot in the rack, where the first slot and the second slot are coupled together via a first interconnect, and a test module that performs an in-system end-to-end signal integrity (SI) performance test of the first interconnect by transmitting a first test signal across the first interconnect via the first test blade, receiving a second test signal from across the first interconnect via the second test blade, and generating a SI performance analysis of the first interconnect based on the first test signal and the second test signal.

In another embodiment, a system comprises a rack, including a first slot, a second slot, and a backplane or midplane. The backplane or midplane could be, for example and without limitation, a printed circuit board (PCB) backplane, a PCB midplane, or a cable cartridge backplane, among others. The circuit board includes a first interconnect coupling the first slot to the second slot. The first interconnect could be, for example and without limitation, direct attach copper (DAC), active copper cable (ACC), active optical cables (AOCs), and so forth. The data center further comprises a first test blade coupled to the first slot, a second test blade coupled to the second slot, and a test module that performs an in-system end-to-end SI performance test of the first interconnect by transmitting a first test signal across the first interconnect via the first test blade, receiving a second test signal from across the first interconnect via the second test blade, and generating a SI performance analysis of the first interconnect based on the first test signal and the second test signal.

In yet another embodiment, a test blade includes a circuit board and an external connector. The circuit board includes a set of traces that couples the circuit board to a first interconnect included in a rack that resides in a data center. The circuit board further includes an internal connector that is coupled to a first trace included in the set of traces. The external connector couples the internal connector to a test module that generates a SI performance analysis of the first interconnect by transmitting a first test signal across the first interconnect via the first trace.

### BRIEF DESCRIPTION OF THE DRAWINGS

FIGS. 1A-1B illustrate a system configured to implement one or more aspects of the various embodiments;

FIGS. 2A-2B are more detailed illustrations of the test blade(s) of FIG. 1, according to various embodiments;

FIG. 3 illustrates an alternative view of a test blade, according to various embodiments;

FIG. 4 is a more detailed illustration of the test module of FIG. 1, according to various embodiments;

FIG. 5 is a flow chart of method steps for diagnosing backplane SI performance degradation in racks, according to various embodiments;

FIG. 6 is an exemplary network architecture, according to various embodiments;

FIG. 7 is a more detailed illustration of the network architecture of FIG. 6, according to various embodiments;

FIG. 8 is a more detailed illustration of the data center of FIGS. 6-7, according to various embodiments; and

FIG. 9 is a computing ecosystem for generating machine learning and artificial intelligence models, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

A rack in a typical data center includes an array of slots where blades can be mounted, as well as a backplane that interconnects the different slots. A given blade is a modular computer system, such as a network or storage device, that can slide into any given slot in the rack. Connectors on the computer system then couple with connectors on the backplane, providing the blade with access to networking resources. Under certain conditions, interconnects within the backplane can experience SI performance degradations that cause increased latency and/or decreased bandwidth between the various slots. A conventional approach to evaluating backplane SI performance degradations involves removing all the blades and the backplane from the rack and then connecting the backplane to testing equipment. This approach requires technical skill, a significant time commitment that involves unplugging all of the blades and cable cartridges to identify issues, and expensive testing equipment.

To address these issues, a first test blade and a second test blade are coupled to first and second slots, respectively, in a rack currently under test. The first test blade is coupled to the second test blade via a first interconnect that forms a portion of a backplane included in the rack. The first test blade and the second test blade are coupled to a diagnostic application that generates and analyzes test signals. The diagnostic application transmits a test signal to the first test blade, which in turn conducts the test signal through the first interconnect to the second test blade. The second test blade returns the test signal to the diagnostic application. The diagnostic application analyzes the transmitted test signal in conjunction with the received test signal in order to identify and isolate specific portions of the first interconnect that are subject to SI performance degradations. The first test blade, the second test blade, and a test module that includes the diagnostic application collectively form a diagnostic instrument that can be used in a data center environment to evaluate SI performance issues associated with racks that include modular computer systems, thereby enabling precise identification of issues related to signal integrity and connectivity. The signal can be measured through the cable cartridge.

In one embodiment, the techniques described herein can be implemented using a single test blade. In a single test blade implementation, a test module such as Time-Domain Reflectometry (TDR) analyzer can be used to transmit a test signal into a test blade that is connected to first suspected failed blade slot. There is no need to remove the regular blade in the second slot. TDR is a technique used to analyze the characteristics of electrical interconnect by sending a signal and observing reflections. TDR is widely used in signal integrity testing, cable fault detection, and high-speed PCB debugging. The TDR analyzer measures the time and amplitude of the reflection to determine where a mismatch occurred (based on round-trip time) and/or what kind of discontinuity is present (based on signal polarity and shape). By doing this way, an end-to-end SI performance test and analysis from suspected failed blade slot backplane connectors to backplane interconnect to the application-specific integrated circuit (ASIC) chips on the second normal blade can be conducted.

The disclosed techniques enable the various interconnects within a backplane to be evaluated for potential SI performance degradations, in an in-system manner, without the need to perform the non-trivial task of removing the backplane. The disclosed techniques enable the troubleshooting of poor performance on specific links without taking down the entire system by using in-system test equipment or test fixtures. In particular, the first and second test blades can be inserted into any pair of slots in the rack in order to perform an end-to-end test of the interconnect coupling together those two slots, without requiring disassembly of the rack itself. Further, the first test blade and/or the second test blade can be moved to other slots in the rack in order to perform additional testing and potentially diagnose other connectivity issues. The disclosed techniques therefore provide a flexible and configurable approach to performing in-system end-to-end testing of interconnects from one blade slot backplane connectors to backplane interconnector to another blade slot backplane connectors or the interconnect all the way to the ASIC chips on the normal blade that is plugged into the second blade slot within racks that reside in manufacturing floors, data centers, and other environments where server racks are deployed.

### System Overview

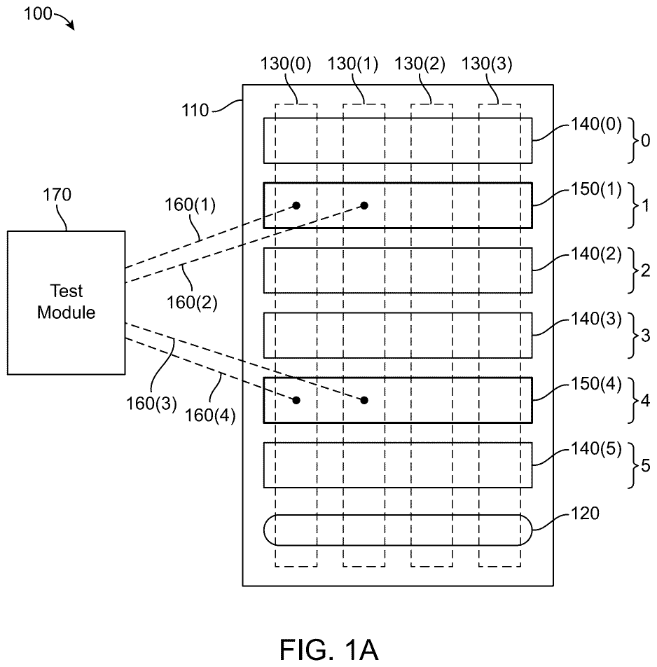

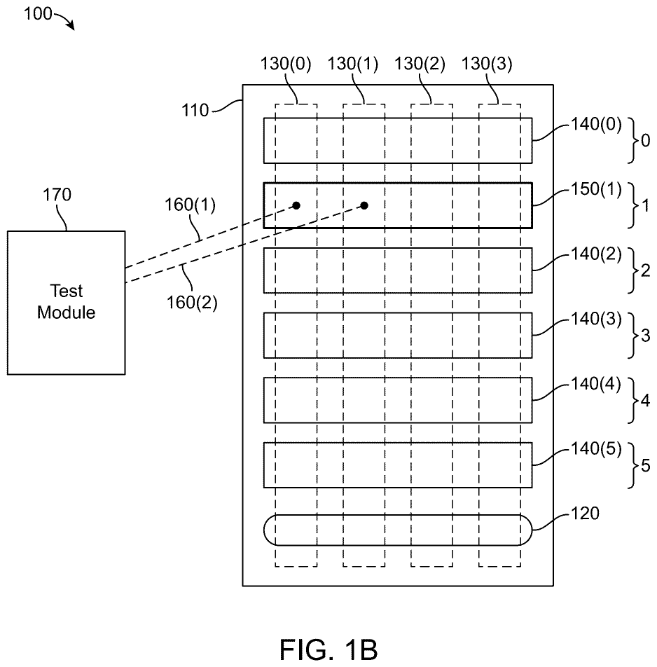

FIGS. 1A-1B illustrate a system 100 configured to implement one or more aspects of the various embodiments. As shown in FIG. 1A, the system 100 includes a rack 110 and a test module 170. The rack 110 is generally organized into different slots 0 through 5. Each slot is configured to receive a modular computing device, such as, for example and without limitation, a blade, a network tray, or a storage tray, among others. In the exemplary configuration shown, a regular blade 140(0) occupies slot 0, a test blade 150(1) occupies slot 1, a regular blade 140(2) occupies slot 2, a regular blade 140(3) occupies slot 3, a test blade 150(4) occupies slot 4, and a regular blade 140(5) occupies slot 5. The rack 110 also includes a backplane 120 that couples together slots 0 through 5 via interconnects 130(0), 130(1), 130(2), and 130(3). The backplane could be, for example and without limitation, a printed circuit board (PCB) backplane, a PCB midplane, or a cable cartridge backplane, among others. The interconnects 130 of the backplane 120 allow the various blades included in the rack 110 to communicate with one another and exchange various types of signals. Test blades 150(1) and 150(4) have a physical form factor that is substantially similar to regular blades 140, thereby allowing test blades 150 to occupy any of slots 0 through 5. In various embodiments, the techniques described herein can be implemented using a single test blade, as shown in FIG. 1B.

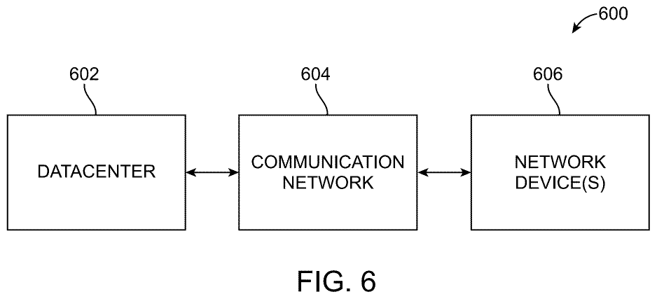

Referring generally to FIGS. 1A-1B, the rack 110 can be any technically feasible type of enclosure that is configured to store modular computing devices, including a network cabinet, server cabinet, or a chassis, for example and without limitation. The backplane 120 can be any technically feasible type of interconnect, including a printed circuit board assembly (PCBA) backplane or a cable cartridge backplane, for example and without limitation. A given regular blade 140 can be any technically feasible type of computer system that is mounted to, or integrated with, a casing of some form that allows the regular blade 140 to be inserted into and extracted from the rack 110. For example, and without limitation, a given regular blade 140 could be a compute tray that provides computing resources, a network tray (e.g. switch tray) that provides networking resources, a storage tray that provides storage resources, and so on. The rack 110 generally resides in a data center or other cloud computing environment. In various embodiments, rack 110 may reside within a data center described in greater detail below in conjunction with FIGS. 6-9.

In the exemplary configuration shown, test module 170 is coupled to test blade 150(1) via cables 160(1) and 160(2) and, similarly, coupled to test blade 150(4) via cables 160(3) and 160(4). In operation, test module 170 is configured to conduct SI performance tests of a given interconnect 130 by transmitting one or more test signals across the given interconnect 130 via one test blade 150 and then receiving one or more response signals from across the given interconnect 130 via the other test blade 150. The test module 170 then analyzes the transmitted test signal(s) in conjunction with the received response signal(s) in order to generate a SI performance analysis that quantifies various SI performance metrics associated with the interconnect 130. Test blades 150(1), 150(4), and the test module 170 collectively form a diagnostic instrument that can evaluate the SI performance of circuit boards, including PCB backplanes, PCB midplanes, and the like.

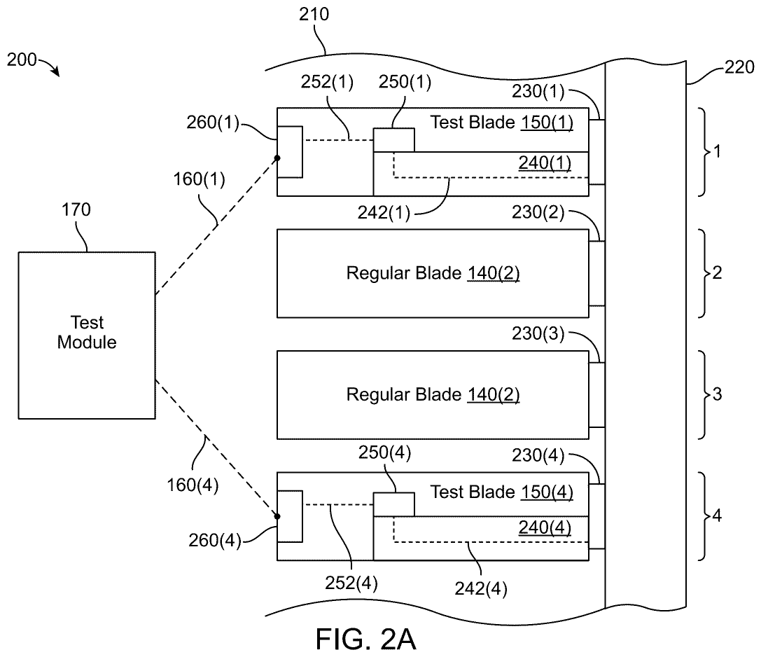

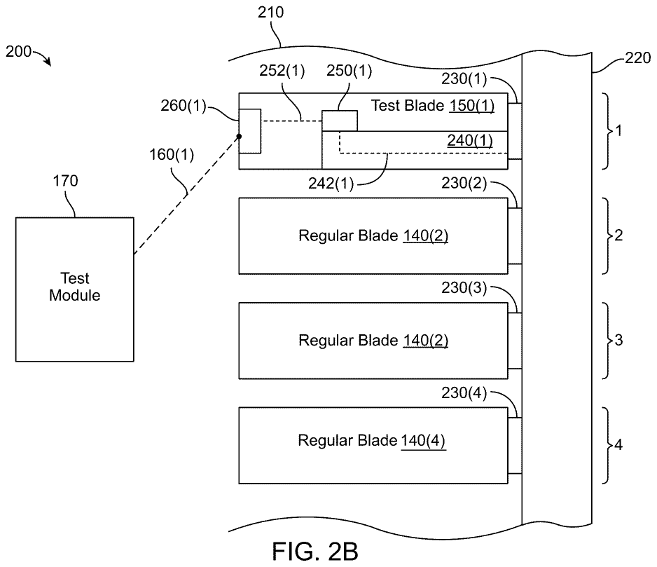

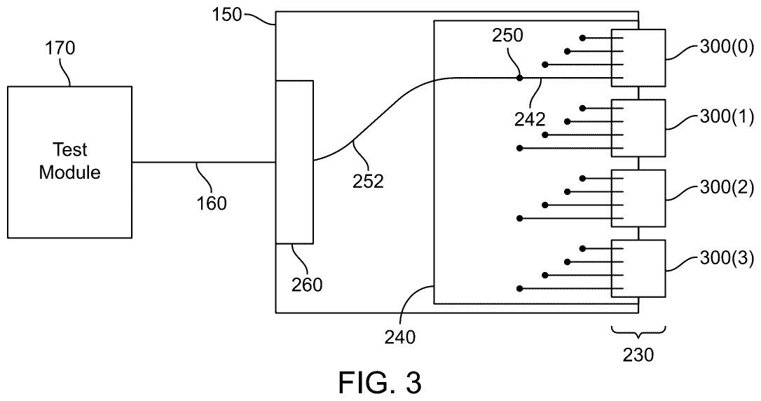

For example, and without limitation, the test module 170 could transmit a test signal via cable 160(1) to test blade 150(1), and test blade 150(1) would in turn conduct the test signal across interconnect 130(0) to test blade 150(4). Test blade 150(4) would receive a response signal that is derived from the test signal and then conduct the response signal back to the test module via cable 160(4). In like fashion, the test module 170 could transmit a test signal via cable 160(4) to test blade 150(4), and test blade 150(4) would in turn conduct the test signal across interconnect 130(0) to test blade 150(1). Test blade 150(1) would receive a response signal that is derived from the test signal and then conduct the response signal back to the test module via cable 160(1). In this manner, the test module 170 can gather test and response signals that can be used to characterize the SI performance of the interconnect 130(0). Then, based on these signals, the test module 170 could generate a SI performance analysis. A similar technique could also be applied to generate a SI performance analysis of interconnect 130(1) using signals transmitted and received via cables 160(2) and 160(3). In addition, the interconnects 130 between any pair of slots 0 through 5 can be tested by inserting test blades 150(1) and 150(4) into those slots and performing any of the techniques described above. In a single test blade implementation, as shown in FIG. 1B, the test module 170 transmits a test signal to the test blade 150(1) in order to diagnose failures associated with the interconnect 130(0). FIGS. 2A-3 set forth an exemplary implementation of test blades 150.

### In-Situ Backplane Interconnect Testing

FIGS. 2A-2B are more detailed illustrations of the test blade(s) of FIG. 1, according to various embodiments. As shown in FIG. 2A, a portion 200 of the system 100 includes a portion 210 of the rack 110 that includes slots 1-4 as well as a portion 220 of the backplane 120. Test blades 150 and regular blades 140 couple to the portion 220 of backplane 120 via connectors 230. As also shown, each test blade 150 includes a fanout printed circuit board (PCB) 240, an internal connector 250, and an external connector 260. A given backplane connector 230 is coupled to a given internal connector 250 via a PCB trace 242. A given internal connector 250 is coupled to a given external connector 260 via a cable 252. A given external connector 260 couples to the test module 170 via a corresponding cable 160. As mentioned above, in various embodiments, the techniques described herein can be implemented using a single test blade, as shown in FIG. 2B.

Referring generally to FIGS. 2A-2B, in various embodiments, the medium of transmission implemented within rack 110 in general or test blade 150 specifically may include any type of networking cable, e.g., direct attach copper (DAC), active copper cable (ACC), active optical cables (AOCs), cable assembly with OSFP connectors or the like, or any interconnect utilized by datacenter racks and associated switch modules (e.g., a Small Form Pluggable (SFP), quad small form-factor pluggable (QSFP), or the like). The medium of transmission may also include a passive copper cable (PCC), an active optical cable and an active optical module for transmitting optical signals. In other alternative cases, any given cable included in test blade 150 may also include an Ethernet cable, active optical cables (AOCs) or a cable assembly with OSFP connectors. The test blade 150 may also include one or more semiconductor devices that may be a pluggable network interface device comprising a male end portion of a direct attach cable assembly (DAC). The test blade 150 may further include network connectors that may each be configured to connect to a networking device of any type (e.g., QSFP, Direct Attach Copper, active optical cables (AOC), etc.), and may thus be dimensioned (e.g., sized and shaped) to mate with or otherwise connect to any corresponding networking device. A given cable connector may be of any type (e.g., an AOC connector, Ethernet connector, Direct Attach Copper connector, Active Optical Module, or the like).

Any given PCB included in the rack 110 or the test blade 150 can be used to electrically connect electronic components using conductive pathways, or traces, etched from metal sheets. In many electronic systems, one or more very large-scale integrated circuit (VLSI) components is coupled to a host system PCB. Such VLSI components may include, for example, central processing unit (CPU) devices and graphics processing unit (GPU) devices. A given PCB may hold at least one processing circuitry. The processing circuitry may comprise hardware, such as an application specific integrated circuit (ASIC). The processing circuitry may comprise an ASIC and/or may be capable of performing as a CPU, a GPU, a network interface controller (NIC), a data processing unit (DPU), a quantum processing unit (QPU), or any other computing device in which data is received and/or transmitted. Other non-limiting examples of the processing circuitry include an Integrated Circuit (IC) chip, a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry.

In various embodiments, a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, PCB 240 may comprise an add-in card, such as a PCIe card, that is configured to be coupled to a system board or motherboard of a host system. In other embodiments, PCB 240 may be the system board or motherboard of the host system itself. Moreover, the system board or the motherboard may be associated with any type of host system. For example, PCB 240 may comprise a system board in a multi-node rack-mounted server in a data center, or it may comprise the motherboard of a workstation, desktop, laptop, or mobile device. Other embodiments are also possible.

In particular, test blade 150(1) includes backplane connector 230(1), fanout PCB 240(1), internal connector 250(1), and external connector 260(1). Backplane connector 230(1) is coupled to internal connector 250(1) via PCB trace 242(1). Internal connector 250(1) is coupled to external connector 260(1) via cable 252(1). External connector 260(1) couples to the test module 170 via cable 160(1). Similarly, test blade 150(4) includes backplane connector 230(4), fanout PCB 240(4), internal connector 250(4), and external connector 260(4). Backplane connector 230(4) is coupled to internal connector 250(4) via PCB trace 242(4). Internal connector 250(4) is coupled to external connector 260(4) via cable 252(4). External connector 260(4) couples to the test module 170 via cable 160(4).

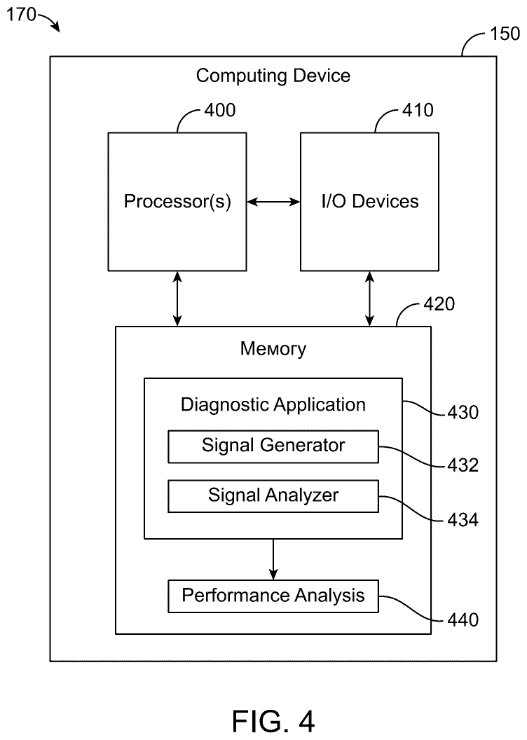

PCB traces 242 may be length and/or impedance-controlled traces configured to normalize and/or compensate for timing and/or impedance mismatches between different communication pathways included in a given interconnect 130 and to avoid reflection and signal degradation, thereby preventing signal loss and maintaining signal integrity. Internal connectors 250 may be land-grid array (LGA) connectors or SubMiniature version A (SMA) connectors, among others. PCB traces 242 may be any technically feasible form of high-speed PCB material. Cables 252 may be any technically feasible form of cable configured to transmit data signals, including, e.g., high-speed cables, without limitation. External connectors 260 may be SMA connectors or any other technically feasible type of connector. In various embodiments, the test module 170 includes one or more of a vector network analyzer (VNA), time-domain reflectometer (TDR), and/or a bit error rate tester (BERT). Any and all operations implemented by the test module 170 can be performed by an exemplary computing device described below in conjunction with FIG. 4. As a general matter, by comparing a test signal and a corresponding response signal, the test module 170 can determine specific types of deficiencies addressing signal integrity problems in the first interconnect 130, such as packet loss, increased error rate, signal attenuation, crosstalk across entire channels in rack-scale or chassis-scale computing environments and the like, for example and without limitation.

FIG. 3 illustrates an alternative view of a test blade, according to various embodiments. As shown, an exemplary test blade 150 includes a backplane connector 230, a fanout PCB 240 that includes impedance and/or length-controlled PCB trace(s) 242, an internal connector 250, a cable 252, and an external connector 260 that couples via a cable 160 to the test module. Backplane connector 230 includes segments 300(0), 300(1), 300(2) and 300(3) that couple to the backplane 120. A given segment 300 may include different logical or physical groupings of pins with which PCB traces 242 are configured to couple with. To conduct a SI performance test, cable 252 can be coupled to different internal connectors 250 and different PCB traces 242 in order to test different portions of various segments 300 of backplane connector 230. In this manner, each discrete communication pathway within the backplane 120 as a whole can be subject to SI performance tests, without the need to disassemble the rack 110 or remove the backplane 120.

Although the test module 170 generally includes any of the VNA/TDR/BERT equipment mentioned above, in one embodiment, the test module 170 may be implemented via a computing device such as that described below in conjunction with FIG. 4.

FIG. 4 is a more detailed illustration of the test module of FIG. 1, according to various embodiments. As shown, the test module 170 includes a computing device 150 having one or more processor(s) 400, input/output (I/O) devices 410, and memory 420, coupled together. As a general matter, computing device 150 could be any technically feasible type of computer system, including a laptop computer, a desktop computer, a handheld computing device, and so forth, for example and without limitation.

Processor(s) 400 may include one or more central processing units (CPUs), graphics processing units (GPUs), quantum processing units (QPUs), parallel processing units (PPUs), application specific integrated circuits (ASICs), field programmable gate arrays (FPGAs), and/or any other technically feasible type of electronic construct configured to process data. QPUs are processors configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

I/O devices 410 may include input devices, such as a keyboard or mouse, without limitation, output devices, such as display devices or acoustic devices, without limitation, and/or devices configured to both receive input and generate output, such as a touchscreen, without limitation. Memory 420 may include one or more random access memory (RAM) modules, one or more hard disks, one or more read-only memory (ROM) modules, or any other technically feasible type of storage construct configured to store data and/or software applications.

Memory 420 includes diagnostic application 430 that, when executed by processor(s) 400, implements the functionality of a signal generator 432 and a signal analyzer 434. Signal generator 432 is configured to generate test signals that can be transmitted to test blades 150. Signal analyzer 434 is configured to analyze response signals in conjunction with the corresponding test signals in order to generate performance analysis 440. Collectively, signal generator 432 and signal analyzer 434 may implement any of the functionality commonly associated with VNA, TDR, and/or BERT testing equipment. Similarly, performance analysis 440 may include any technically feasible metrics associated with such testing equipment.

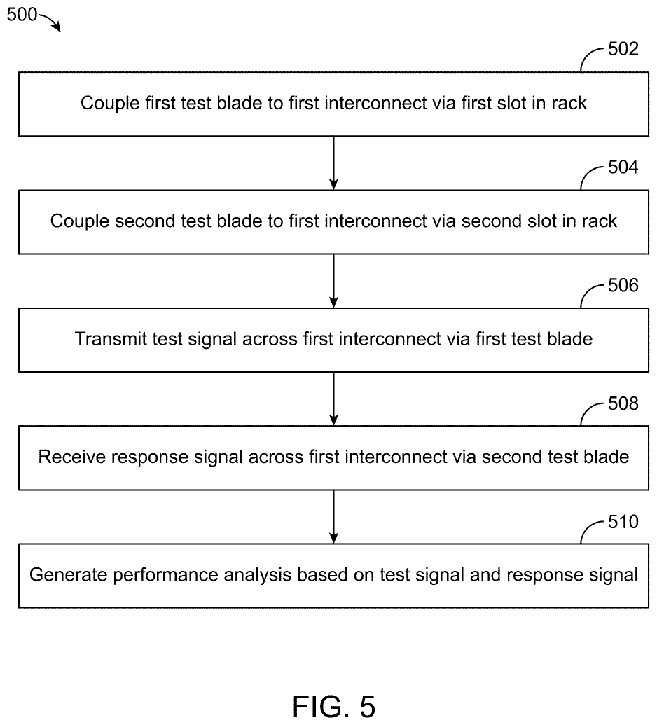

FIG. 5 is a flow chart of method steps for diagnosing backplane SI performance degradations in racks, according to various embodiments. Although the method steps are described in conjunction with the systems of FIGS. 1-4, persons skilled in the art will understand that any system configured to perform the method steps, in any order, is within the scope of the present embodiments.

As shown, a method 500 begins at step 502, where a first backplane connector 230 couples a first test blade 150 to a first interconnect 130 via a first slot in the rack 110. The first test blade 150 includes internal circuitry configured to couple the test module 170 to the interconnect 130 in order to evaluate potential SI performance degradations associated with the first interconnect 130.

At step 504, a second backplane connector 230 couples a second test blade 150 to a first interconnect 130 via second slot in the rack 110. The second test blade 150 also includes internal circuitry configured to couple the test module 170 to the interconnect 130 when evaluating potential SI performance degradations associated with the first interconnect 130. FIGS. 2-3 set forth exemplary implementations of such internal circuitry.

At step 506, the test module 170 transmits a test signal across the first interconnect 130 via the first test blade 150. The test module 170 transmits the test signal via a cable 160 that couples to the internal circuitry of the first test blade 150. The first test blade 150 then conducts the test signal to the second test blade via the first interconnect 130.

At step 508, the test module 170 receives a response signal across the first interconnect 130 via the second test blade 150. The response signal is derived from the test signal and may be subject to various types of degradations caused by defects in the first interconnect 130.

At step 510, the test module 170 generates a SI performance analysis 440 based on the test signal and the response signal. By comparing the test signal and the response signal, the test module 170 can determine specific types of deficiencies in the first interconnect 130, such as packet loss, increased error rate, signal attenuation, and the like, for example and without limitation. The test module 170 then generates the SI performance analysis 440 to indicate these various findings.

In sum, a first test blade and a second test blade are coupled to first and second slots, respectively, in a rack currently under test. The first test blade is coupled to the second test blade via a first interconnect that forms a portion of a backplane included in the rack. The first test blade and the second test blade are coupled to a diagnostic application that generates and analyzes test signals. The diagnostic application transmits a test signal to the first test blade, which in turn conducts the test signal through the first interconnect to the second test blade. The second test blade returns the test signal to the diagnostic application. The diagnostic application analyzes the transmitted test signal in conjunction with the received test signal in order to identify specific portions of the first interconnect that are subject to SI performance degradations. The first test blade, the second test blade, and a test module that includes the diagnostic application collectively form a diagnostic instrument that can be used in a data center environment to evaluate SI performance issues associated with racks that include modular computer systems. In single test blade implementations, the diagnostic instrument may include the first test blade and the test module.

The disclosed techniques enable the various interconnects within a backplane to be evaluated for potential SI performance degradations, in an in-system manner, without the need to perform the non-trivial task of removing the backplane to measure signal quality directly in the rack. In particular, the first and second test blades can be inserted into any pair of slots in the rack in order to perform an end-to-end test of the interconnect coupling together those two slots, without requiring disassembly of the rack itself. Further, the first test blade and/or the second test blade can be moved to other slots in the rack in order to perform additional testing and potentially diagnose other connectivity issues. The disclosed techniques therefore provide a flexible and configurable approach to performing in-system end-to-end testing of interconnects within racks that reside in manufacturing floors, data centers, and other environments where server racks are deployed.

In various embodiments, a manufacturing tester or test rack uses the single test blade implementation because each slot has a backplane, sometimes referred to as a loopback cable or loopback PCB, that is used to connect the transmitter and receiver for loopback testing within the same blade. In this configuration the test blade does not connect to other slots within the manufacturing tester. As a general matter, a manufacturing tester is different than a regular data center rack. A manufacturing tester is used to house individual blades for testing before the blades are integrated into a data center rack. Each slot in the tester is standalone, and the slots are not connected by backplanes.

Data centers and other networking systems may include connections between data centers, switch systems, servers, racks, and devices in order to provide for signal transmission between one or more of these elements. These connections may be made using cables, transceivers, interconnects, interposers, and connector assemblies. For high bandwidth applications and/or connections over long distances, high powered optical communications may be preferred to ensure signal transmission integrity.

Data centers may include multiple network switches in a particular topology, such as a fat tree topology, a slim fly topology, a dragonfly topology, multi-level fat-trees, fat-flys, Benes, Clos, meshes, and tori and/or the like. The specifications and makeup of the network switches in the topology affects the overall network performance (e.g., bandwidth capability) of the data center.

Data centers are the storage and data processing hubs of the internet. The massive deployment of cloud applications is causing data centers to expand exponentially in size, stimulating the development of faster switches than can cope with the increasing data traffic inside the data center. Current state-of-the-art switches are capable of handling 12.8 Tb/s of traffic by employing electrical switches in the form of application specific integrated circuits (ASICs) equipped with 256 data lanes, each operating at 50 Gb/s. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

### Example Data Center Environment

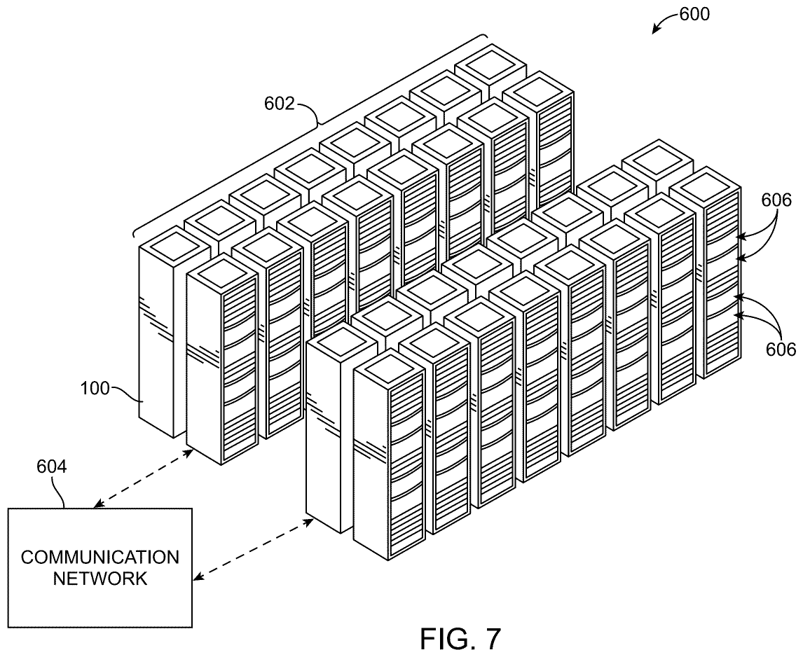

As described above, data centers, high performance computing clusters, and/or the like are often formed of various computing components or networked devices, and communication networks formed of electrical and/or optical devices may be used to enable communication between the networked devices forming these implementations. With reference to FIGS. 6-7, for example and without limitation, a network architecture 600 may include a data center 602, a communication network 604, and one or more network device(s) 606. In various embodiments, the data center 602 includes an instance of the rack 110 of FIG. 1, configured to include test blades 150 coupled to the test module 170, as also shown in FIG. 1. The network architecture 600 may illustrate a general computing architecture within which more specific systems and/or subsystems may function. Although described hereinafter with reference to a network architecture 600 and/or data center 602 within which embodiments of the present disclosure may be implemented, the present disclosure contemplates that the various techniques described herein may be applicable to any network architecture, without limitation.

The data center 602 may be a centralized facility designed to house computing resources and related components. The data center 602 may operate to support the infrastructure required for advanced computational tasks, for efficient, secure, and reliable operations. The data center 602 may include the building and structural components, including power supplies, cooling systems, fire suppression systems, and physical security measures that are configured to maintain optimal operating conditions and/or protect the equipment from environmental hazards and unauthorized access. An example data center 602 may include high-performance servers or compute nodes, often arranged in racks, such as those illustrated in FIG. 7, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

In various embodiments, the data center 602 corresponds to a collection of network devices and may include various high-speed network equipment, such as network switches (e.g., Ethernet switches, IP routers, multiservice platforms, various transmission network elements, legacy communication equipment, or in any other suitable communication system), routers, firewalls, and/or the like to facilitate fast and secure data transmission within the data center 602 (e.g., between servers or compute nodes) and between external networks. The data center 602 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the data center 602 may support high-performance computing tasks. Examples of various network topologies may include hierarchical networking topologies such as the fat tree topology, Slim Fly topology, Dragonfly topology, and/or the like, as also mentioned above.

The communication network 604 may communicably couple the data center 602 with network device(s) 606 and other external devices for data exchange and connectivity. Examples of the communication network 604 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 604 to incorporate multiple network types and configurations may allow the data center 602 to adapt to diverse application needs, from general data communication to specialized HPC tasks. As described herein, the communication network 604 may leverage various optical components to establish communication links (e.g., communicably couple) between components in the network architecture 600. As such, the communication network 604 may include various optical devices, transceivers, modules, and/or the like that are configured to generate optical signals (e.g., provide optical transmitter functionality) and/or receive optical signals (e.g., provide optical receiver functionality) via optical fibers or other optical communication media in order to establish connection between various devices in the network architecture 600. In one specific but non-limiting example, the communication network 604 is a network that enables data transmission between network devices 608 using data signals (e.g., digital, optical, wireless signals).

The network device(s) 606 may include a variety of computing devices capable of transmitting and receiving signals over the communication network 604. The network device(s) 606 may range from personal computing devices to complex server configurations. Examples include Personal Computers (PCs), laptops, tablets, smartphones, or one or more servers. The network device(s) 606 may facilitate user interactions with the data center 602, allowing for data input, retrieval, and processing from remote locations. In addition to individual computing devices, the network device(s) 606 may also include collections of servers or additional data centers. For instance, these could be other data centers similar to or the same as data center 602. Such an interconnection may allow for the formation of a distributed computing environment for improved redundancy, load balancing, and disaster recovery capabilities. By linking multiple data centers, the network architecture 600 may leverage geographically dispersed resources, optimizing performance and ensuring high availability.

As described herein, the data center 602 and/or the network device(s) 606 may include storage devices and processing circuitry for executing computing tasks, such as controlling the flow of data internally and over the communication network 604. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the data center 602 and network device(s) 606 may include one or more communication interfaces for facilitating wired and/or wireless communication between one another and other unillustrated elements of the network architecture 600. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 600.

Furthermore, the present disclosure contemplates that the network architecture 600 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 600 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 600.

In various embodiments, a switch fabric serves to transfer data between switch ports included in the network architecture 600 and/or one or more data centers 602. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The data center 602 routes traffic amongst the network switches and servers therein, and at least one layer of the topology in the data center 602 is coupled to the communication network 604 to allow networking traffic to flow between the data center 602 and the network device(s) 606.

As discussed above, the communication network 604 can be implemented using various types of networks and/or combinations of different types of networks. Each type of network offers specific advantages tailored to different operational requirements. For instance, an IP network or Ethernet network may provide widespread compatibility and ease of integration, supporting various protocols and applications across the data center 602 and the network device(s) 606 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

In various embodiments, the network device(s) 606 may include a variety of computing devices capable of sending and receiving signals over the communication network 604. The network device(s) 606 can range from personal computing devices to complex server configurations. Examples include Personal Computers (PCs), laptops, tablets, smartphones, or one or more servers, as mentioned. In at least one example embodiment, the one or more network devices 606 correspond to another data center, similar to or the same as data center 602. The network device(s) 606 may facilitate user interactions with the data center 602, allowing for data input, retrieval, and processing from remote locations. In addition to individual computing devices, the network device(s) 606 may also include collections of servers or additional data centers. For instance, these could be other data centers similar to or the same as data center 602. Such an interconnection may allow for the formation of a distributed computing environment for improved redundancy, load balancing, and disaster recovery capabilities. By linking multiple data centers, the network architecture 600 can leverage geographically dispersed resources, optimizing performance and ensuring high availability.

The data center 602 and/or the network device(s) 606 may include storage devices and/or processing circuitry for carrying out computing tasks, for example, and without limitation, tasks associated with controlling the flow of data internally and/or over the communication network 604. Such processing circuitry may comprise software, hardware, or a combination thereof. For example, and without limitation, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry may comprise hardware, such as an application specific integrated circuit (ASIC). Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the data center 602 and network device(s) 606 may include one or more communication interfaces for facilitating wired and/or wireless communication between one another and other unillustrated elements of the network architecture 600. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 600. Furthermore, it should be understood that the network architecture 600 may include additional components and functionalities within the scope of the present disclosure.

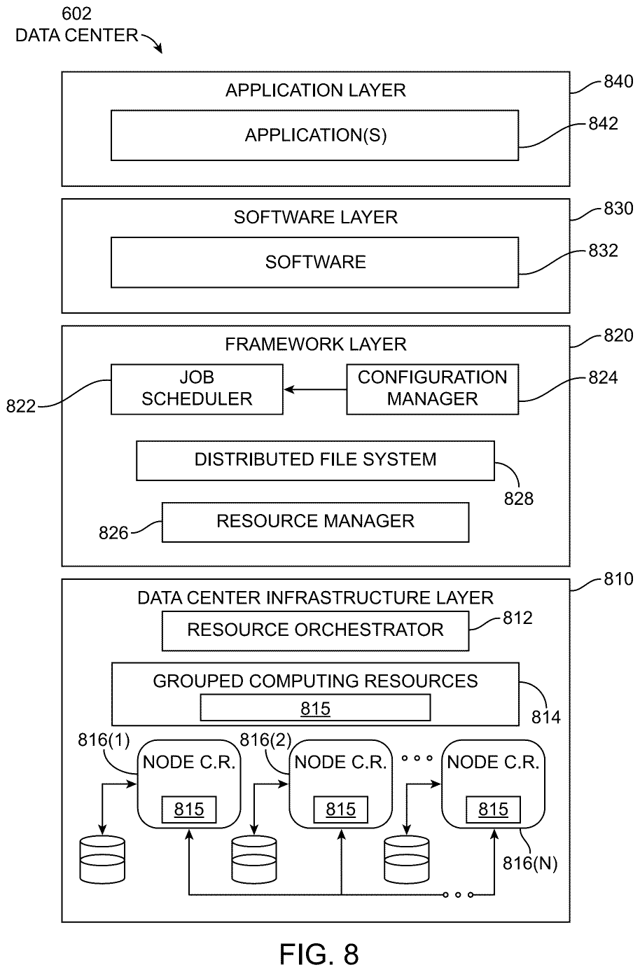

FIG. 8 illustrates an example data center 602, in which at least one embodiment may be used. In at least one embodiment, data center 602 includes a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents a positive integer (which may be a different integer “N” than used in other figures). In at least one embodiment, node C.R.s 816(1)-816(N) may include, but are not limited to, any number of central processing units (“CPUs”) or other processors (including accelerators, field programmable gate arrays (FPGAs), graphics processors, etc.), memory storage devices 818(1)-818(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). In at least one embodiment, separate groupings of node C.R.s within grouped computing resources 814 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 812 may configure or otherwise control one or more node C.R.s 816(1)-816(N) and/or grouped computing resources 814. In at least one embodiment, resource orchestrator 812 may include a software design infrastructure (“SDI”) management entity for data center 602. In at least one embodiment, resource orchestrator 812 may include hardware, software or some combination thereof.

In at least one embodiment, as shown in FIG. 8, framework layer 820 includes a job scheduler 822, a configuration manager 824, a resource manager 826 and a distributed file system 828. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may use distributed file system 828 for large-scale data processing (e.g., “big data”). In at least one embodiment, job scheduler 822 may include a Spark driver to facilitate scheduling of workloads supported by various layers of data center 602. In at least one embodiment, configuration manager 824 may be capable of configuring different layers such as software layer 830 and framework layer 820 including Spark and distributed file system 828 for supporting large-scale data processing. In at least one embodiment, resource manager 826 may be capable of managing clustered or grouped computing resources mapped to or allocated for support of distributed file system 828 and job scheduler 822. In at least one embodiment, clustered or grouped computing resources may include grouped computing resources 814 at data center infrastructure layer 810. In at least one embodiment, resource manager 826 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 828 of framework layer 820. In at least one embodiment, one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 828 of framework layer 820. In at least one embodiment, one or more types of applications may include, but are not limited to, any number of a genomics application, a cognitive compute application, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 824, resource manager 826, and resource orchestrator 812 may implement any number and type of self-modifying actions based on any amount and type of data acquired in any technically feasible fashion. In at least one embodiment, self-modifying actions may relieve a data center operator of data center 602 from making possibly bad configuration decisions and possibly avoiding underused and/or poor performing portions of a data center.

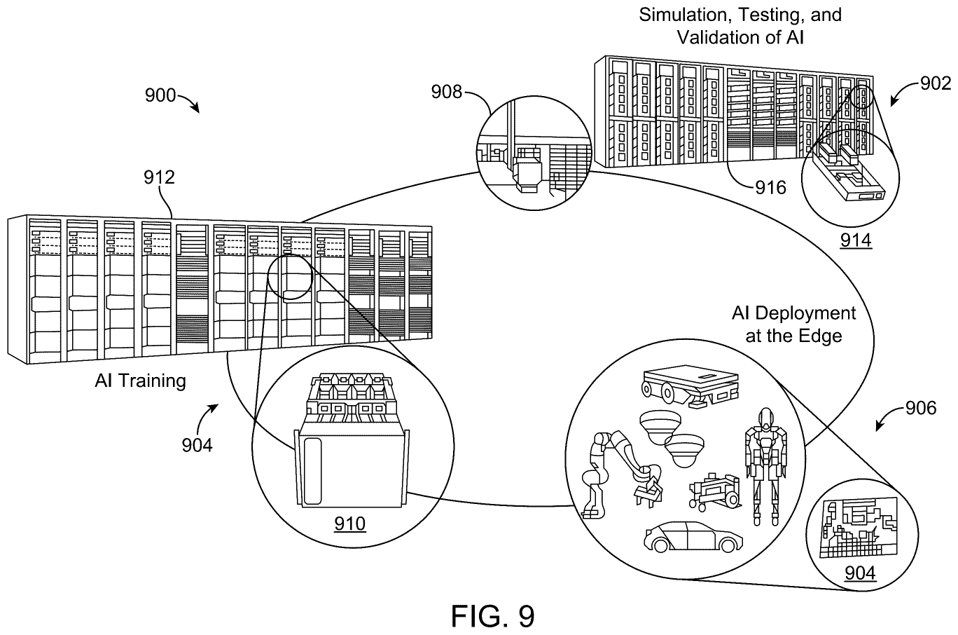

In at least one embodiment, data center 602 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 602. In at least one embodiment, trained machine learning models corresponding to one or more neural networks may be used to infer or predict information using resources described above with respect to data center 602 by using weight parameters calculated through one or more training techniques described herein. An exemplary computing ecosystem for generating, training, and deploying AI is described below in conjunction with FIG. 9.

### Computing Ecosystem for Generating, Training, and Deploying AI

FIG. 9 is a system diagram illustrating a three-computer ecosystem 900, including a first computing system 902 for generating or creating artificial intelligence (AI)-such as AI training and validation data, a second computing system 904 for training artificial intelligence, and a third computing system 906 (which may include or correspond to a system on Chip) deploying the AI at the edge, in accordance with at least some embodiments of the present disclosure. For example, to develop and deploy embodied or physical AI, the three-computer ecosystem 900 may be used, including three accelerated computer systems to handle physical AI training, simulation, and runtime (e.g., edge deployment). These systems may generate training data for and train multimodal foundation models (and/or other model types) using scalable, physically based simulations of the machine(s) and their worlds. By doing so, simulation of physical or virtual machine(s) may be performed at scale, allowing for refinement, testing, and optimization of skills (e.g., robot skills) in a virtual world (e.g., using NVIDIA's OMNIVERSE) that mimics the laws of physics-helping to reduce real-world data acquisition costs and ensuring the machine(s) can perform safely in controlled settings.

The computing system 904 (e.g., NVIDIA's DGX Platform) may be used to train and fine-tune powerful foundation and generative AI models. Models, such as general purpose foundation models (e.g., NVIDIA's Project GR00T), may be used to enable robots and other machine(s) to understand natural language and emulate movements by observing human actions. The computing system 904 may include a platform that incorporates software, infrastructure, and expertise in a modern, unified AI development and training solution. The computing system 904 may include individual computing devices 910 (e.g., NVIDIA's DGX B200, H200, etc.) and/or any number of computing devices 910 in a data center infrastructure 912 (e.g., NVIDIA's DGX SuperPOD).

For example, the individual computing devices 910 may include GPUs (e.g., 8 GPUs with 1,440 GB total GPU memory) and CPUs (e.g., 2 CPUs with 112 cores total, 2.1 GHz, or 4 GHz (with boost)) that provide upwards of 72 petaFLOPS for training and 144 petaFLOPS for inference. The computing devices 910 may include memory (e.g., 4 TB memory, and storage (e.g., OS storage of 2×1.9 TB NVMe M.2, and internal storage of 8×3.84 TB NVMe U.2). The computing devices 910 may include various networking and network management components, such as OSFP ports (e.g., 4 OSFP ports) serving single-port smart host channel adapters (e.g., 8 single port ConnextX-7 virtual protocol interconnects (VPIs)), providing up to 400 GB/s Infiniband/Ethernet. The computing devices 910 may further include, e.g., dual port quad small form-factor pluggable (QSFFP) data processing units (DPUs) (e.g., 2 dual-port QSFP112 DPUs such as NVIDIA's BlueField-3 DPUs), providing up to 400 Gb/s InfiniBand/Ethernet. The computing device(s) 910 may include an onboard network interface controller (NIC) (e.g., 10 Gb/s onboard NIC with RJ45), a dual-port Ethernet NIC (e.g., 100 GB/s dual-port Ethernet NIC), and/or a host baseboard management controller (MBC) (e.g., with RJ45). In some embodiments, the NICs used for the computing device(s) 910 may include SuperNICs (e.g., NVIDIA's ConnectX-8 SuperNIC) to provide up to 800 Gb/s of data throughput for in-network computing acceleration engines to deliver the performance and robust feature set needed to power trillion-parameter scale AI factories and scientific computing workloads. In other embodiments, the computing device(s) 910 may include a smart host channel adapter (HCA) (e.g., NVIDIA's ConnectX-7) to provide ultra-low latency, 400 Gb/s throughput for in-network computing acceleration engines.

The data center infrastructure 912 may include any number of the computing devices 910, along with an operating system (OS) (e.g., DGX OS extensions for Linux distributions) to maximize system uptime, security, and reliability, network/storage acceleration libraries and management to accelerate end-to-end infrastructure performance, cluster management to scale and manage one node (e.g., one computing device 910) to thousands, job scheduling and orchestration to ensure hassle-free execution of every developer's job, AI workflow management and machine learning operations (MLOps) to move more models from prototype to production, and enterprise software to speed developer success.

The computing system 902 (e.g., NVIDIA's OVX servers) may provide a development and simulation platform for testing and optimizing physical AI with APIs and frameworks for simulation (e.g., NVIDIA's DriveSIM, ISAAC Sim, ISAAC Gym, ISAAC Lab, etc.). The computing system 902 allows developers to use simulation frameworks to simulate and validate robot models, and/or to generate massive amounts of physically-based synthetic data to bootstrap model training. The computing system 902 may support learning frameworks that power robot reinforcement learning and imitation learning, to accelerate robot policy training and refinement. For example, the computing system 902 may be used to generate any number of simulations 908—such as within NVIDIA's OMNIVERSE. The computing system 902 may be used optimized for accelerating an entire software stack, from training, fine-tuning, and deploying generative AI to powering industrial digitalization within a content collaboration platform of APIs, software developer kits (SDKs), and services that allow for integration of OpenUSD, ray-tracing rendering technologies (e.g., NVIDIA's RTX), and generative physical AI into existing software tools and simulation workflows for, e.g., industrial and robotics use cases (e.g., NVIDIA's OMNIVERSE). As such, the computing system 902 may host or support a native OpenUSD software platform enabling enterprises to connect 3D pipelines and develop advanced, real-time 3D applications for industrial digitalization. With powerful ray-tracing-accelerated AI and graphics capabilities, the computing system 902 delivers powerful performance for workloads like extended reality (XR), multi-user design collaboration, and digital twins. This allows creation of physically accurate models with high-fidelity ray-traced and path-traced rendering of materials, operation of large-scale, AI-enabled simulations, and generation of photorealistic 3D synthetic data for training. The computing system 902 may include individual computing devices 914 (e.g., NVIDIA's OVX L40S Server) and/or any number of computing devices 914 in a data center infrastructure 916 (e.g., NVIDIA's OVX Systems).

The computing device(s) 914 (which may include a server) may include CPUs (e.g., 2 CPUs with 32 cores each), and GPUs (e.g., 4 or 8 GPUs, each including 48 GB GDDR 6 with ECC memory, 864 GB/s memory bandwidth, PCIe Gen 4×16:64 GB/s bidirectional interconnect interface, 18,176 CUDA cores, 142 ray tracing (RT) cores, and 568 tensor cores). The computing devices 914 may include various networking and network management components, such as smart host channel adapters (HCA) (e.g., 2 or 4 single port ConnextX-7 at 200 Gb/s each, providing up to 800 Gb/s Infiniband/Ethernet), one or more DPUs (e.g., a dual-port QSFP112 DPUs-such as an NVIDIA BlueField-3 DPU), providing up to 400 Gb/s InfiniBand/Ethernet. In some embodiments, the NICs used for the computing device(s) 914 may include SuperNICs (e.g., NVIDIA's ConnectX-8 SuperNIC) to provide up to 800 Gb/s of data throughput for in-network computing acceleration engines to deliver the performance and robust feature set needed to power trillion-parameter scale AI factories and scientific computing workloads. In other embodiments, the computing device(s) 914 may include a smart host channel adapter (HCA) (e.g., NVIDIA's ConnectX-7) to provide ultra-low latency, 400 Gb/s throughput for in-network computing acceleration engines. The computing device(s) 914 may include a host memory (e.g., 384 Gb DDR 5 ECC for 4 GPUs, or 768 Gb DDR 5 ECC for 8 GPUs), and may include a dual in-line memory module (DIMM) slot(s), a host boot drive (e.g., 1 TB NVMe), and/or a host storage (e.g., 2 4 TB NVMe).

Similar to the data center infrastructure 912, the data center infrastructure 916 may allow for any number of computing device(s) 914 to be combined in cluster configuration according to a reference architecture.

The computing system 906 may be used to deploy trained AI models on a runtime computer-such as a system-on-chip. For example, these computing systems 906 may be designed for compact, on-board computing needs, including an ensemble of models for control policy, vision and language models, etc., deployed on a power-efficient on-board edge computing system 906.

In various embodiments, any element of the three-computer-ecosystem 900 may be implemented via any component described in conjunction with FIGS. 6-8. Further, the three-computer ecosystem 900 may reside within the network architecture 600 or overlap at least a portion of the network architecture 600. For example, and without limitation, the data center infrastructure 912 may be implemented via one or more data centers 602, while the computing system 904 may be implemented via one or more network devices 606. Persons skilled in the art will understand that the three-computer ecosystem 900 represents just one possible implementation of the network architecture 600.
1. Some embodiments include a diagnostic instrument, comprising a first test blade coupled to a first slot in a rack, a second test blade coupled to a second slot in the rack, wherein the first slot and the second slot are coupled together via a first interconnect, and a test module that performs an in-system end-to-end signal integrity (SI) performance test of the first interconnect by transmitting a first test signal across the first interconnect via the first test blade, receiving a second test signal from across the first interconnect via the second test blade, and generating a SI performance analysis of the first interconnect based on the first test signal and the second test signal.
2. The diagnostic instrument of clause 1, wherein the first test blade includes a printed circuit board that compensates for timing mismatches between communication pathways included in the first interconnect.
3. The diagnostic instrument of any of clauses 1-2, wherein the first test blade includes a printed circuit board that compensates for impedance mismatches between communication pathways included in the first interconnect.
4. The diagnostic instrument of any of clauses 1-3, wherein the first test blade includes a plurality of length and impedance controlled printed circuit board traces that compensates for timing and impedance mismatches associated with a plurality of communication pathways included in the first interconnect.
5. The diagnostic instrument of any of clauses 1-4, wherein then first interconnect resides in a backplane or midplane that comprises a printed circuit board assembly or a cable cartridge backplane or midplane.
6. The diagnostic instrument of any of clauses 1-5, wherein the test module comprises a vector network analyzer, or a time-domain reflectometer, or a bit error rate tester.
7. The diagnostic instrument of any of clauses 1-6, further comprising a computing device, including a processor, and a memory storing program instructions that, when executed by the processor cause the processor to transmit the first test signal across the first interconnect via the first test blade, receive the second test signal from across the first interconnect via the second test blade, and generate the SI performance analysis of the first interconnect based on the first test signal and the second test signal.
8. The diagnostic instrument of any of clauses 1-7, wherein each of the first test blade and the second test blade has a form factor that is substantially similar to a regular blade.
9. The diagnostic instrument of any of clauses 1-8, wherein the SI performance analysis quantifies at least one packet loss, error rate, or signal attenuation.
10. The diagnostic instrument of any of clauses 1-9, wherein the test module further performs the in-system end-to-end SI performance test of the first interconnect by transmitting a third test signal across the first interconnect via the second test blade, and receiving a fourth test signal from across the first interconnect via the first test blade, wherein the SI performance analysis of the first interconnect is further generated based on the third test signal and the fourth test signal.
11. Some embodiments include a system, comprising a rack, including a first slot, a second slot, and a backplane or midplane that includes a first interconnect coupling the first slot to the second slot, a first test blade coupled to the first slot, a second test blade coupled to the second slot, and a test module that performs an in-system end-to-end signal integrity (SI) performance test of the first interconnect by transmitting a first test signal across the first interconnect via the first test blade, receiving a second test signal from across the first interconnect via the second test blade, and generating a SI performance analysis of the first interconnect based on the first test signal and the second test signal.
12. The system of clause 11, wherein the first test blade includes a printed circuit board that compensates for timing mismatches between communication pathways included in the first interconnect.
13. The system of any of clauses 11-12, wherein the first test blade includes a printed circuit board that compensates for impedance mismatches between communication pathways included in the first interconnect.
14. The system of any of clauses 11-13, wherein the first test blade includes a plurality of length and impedance controlled printed circuit board traces that compensate for timing and impedance mismatches associated with a plurality of communication pathways included in the first interconnect.
15. The system of any of clauses 11-14, wherein the backplane or midplane comprises a printed circuit board assembly or a cable cartridge backplane or midplane that includes a plurality of high-speed cables.
16. The system of any of clauses 11-15, wherein the test module comprises a vector network analyzer (VNA), or a time-domain reflectometer (TDR), or a bit error rate tester (BERT).
17. The system of any of clauses 11-16, further comprising a computing device, including a processor, and a memory storing program instructions that, when executed by the processor, cause the processor to transmit the first test signal across the first interconnect via the first test blade, receive the second test signal from across the first interconnect via the second test blade, and generate the SI performance analysis of the first interconnect based on the first test signal and the second test signal.
18. The system of any of clauses 11-17, wherein each of the first test blade and the second test blade has a form factor that is substantially similar to a regular blade.
19. The system of any of clauses 11-18, wherein the test module performs a second in-system end-to-end SI performance test of a second interconnect by transmitting a third test signal across the second interconnect via the first test blade, receiving a fourth test signal from across the second interconnect via the second test blade, and generating a second SI performance analysis of the second interconnect based on the third test signal and the fourth test signal.
20. Some embodiments include a test blade, comprising a circuit board, including a set of traces that couples the circuit board to a first interconnect included in a rack via a connector type that resides on a regular blade, and an internal connector that is coupled to a first trace included in the set of traces, and an external connector that couples the internal connector to a test module, wherein the test module generates a signal integrity (SI) performance analysis of the first interconnect by transmitting a first test signal across the first interconnect via the first trace.
21. The test blade of clause 20, wherein the first interconnect resides in a backplane or midplane included in the rack, and further comprising a backplane or midplane connector, including a first segment that couples the first trace to the first interconnect, wherein the first segment corresponds to a logical or a physical grouping associated with the backplane or midplane, and a second segment that couples a second trace to the first interconnect, wherein the second segment corresponds to a different logical or a different physical grouping associated with the backplane or midplane.
22. The test blade of claim 20, wherein the internal connector comprises a land-grid array (LGA) connector or a SubMiniature version A (SMA) connector, wherein the internal connector is coupled to the external connector via a high-speed cable, wherein a mounting location of the internal to the first trace is adjustable based on the SI performance analysis, and wherein the test module is coupled to a failed first path during end-to-end SI performance testing and analysis from the first trace to the first interconnect and to a second trace on a second blade that is interconnected with the backplane in another slot.
23. The test blade of clause 20, wherein the set of traces compensates for timing and impedance mismatches associated with a plurality of communication pathways included in the first interconnect.
24. The test blade of any of clauses 22-23, wherein the rack comprises a manufacturing tester or test rack and the backplane comprises a loopback printed circuit board.
25. Some embodiments include a diagnostic instrument, comprising a first test blade coupled to a first slot in a rack, wherein the first slot is coupled to a first interconnect, and a test module that performs an in-system end-to-end SI performance test of the first interconnect by transmitting a first test signal across the first interconnect via the first test blade, and generating a SI performance analysis of the first interconnect based on the first test signal.
26. The diagnostic instrument of clause 25, wherein the first test blade includes a printed circuit board that compensates for timing mismatches between communication pathways included in the first interconnect.
27. The diagnostic instrument of any of clauses 25-26, wherein the first test blade includes a printed circuit board that compensates for impedance mismatches between communication pathways included in the first interconnect.
28. The diagnostic instrument of any of clauses 25-27, wherein the first test blade includes a plurality of length and impedance controlled printed circuit board traces that compensates for timing and impedance mismatches associated with a plurality of communication pathways included in the first interconnect.
30. The diagnostic instrument of any of clauses 25-29, wherein the test module comprises a vector network analyzer, or a time-domain reflectometer, or a bit error rate tester.
31. The diagnostic instrument of any of clauses 25-30, further comprising a computing device, including a processor, and a memory storing program instructions that, when executed by the processor cause the processor to transmit the first test signal across the first interconnect via the first test blade, and generate the SI performance analysis of the first interconnect based on the first test signal.
32. The diagnostic instrument of any of clauses 25-31, wherein the first test blade has a form factor that is substantially similar to a regular blade.
33. The diagnostic instrument of any of clauses 25-32, wherein the SI performance analysis quantifies at least one packet loss, error rate, or signal attenuation.
34. Some embodiments include a data center, comprising a rack, including a first slot, a second slot, and a backplane or midplane that includes a first interconnect coupling the first slot to the second slot, a first test blade coupled to the first slot, a second test blade coupled to the second slot, and a test module that performs an in-system end-to-end performance test of the first interconnect by transmitting a first test signal across the first interconnect via the first test blade, receiving a second test signal from across the first interconnect via the second test blade, and generating a performance analysis of the first interconnect based on the first test signal and the second test signal.
35. The data center of clause 34, wherein the first test blade includes a printed circuit board that compensates for timing mismatches between communication pathways included in the first interconnect.
36. The data center of any of clauses 34-35, wherein the first test blade includes a printed circuit board that compensates for impedance mismatches between communication pathways included in the first interconnect.
37. The data center of any of clauses 34-36, wherein the first test blade includes a plurality of length and impedance controlled printed circuit board traces that compensate for timing and impedance mismatches associated with a plurality of communication pathways included in the first interconnect.
38. The data center of any of clauses 34-37, wherein the backplane or midplane comprises a printed circuit board assembly or a cable cartridge backplane or midplane that includes a plurality of high-speed cables.
39. The data center of any of clauses 34-38, wherein the test module comprises a vector network analyzer (VNA), a time-domain reflectometer (TDR), or a bit error rate tester (BERT).
40. The data center of any of clauses 34-39, further comprising a computing device, including a processor, and a memory storing program instructions that, when executed by the processor, cause the processor to transmit the first test signal across the first interconnect via the first test blade, receive the second test signal from across the first interconnect via the second test blade, and generate the performance analysis of the first interconnect based on the first test signal and the second test signal.
41. The data center of any of clauses 34-40, wherein each of the first test blade and the second test blade has a form factor that is substantially similar to a regular blade.
42. The data center of any of clauses 34-41, wherein the test module performs a second in-system end-to-end performance test of a second interconnect by transmitting a third test signal across the second interconnect via the first test blade, receiving a fourth test signal from across the second interconnect via the second test blade, and generating a second performance analysis of the second interconnect based on the third test signal and the fourth test signal.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A diagnostic instrument, comprising:
a first test blade coupled to a first slot in a rack;
a second test blade coupled to a second slot in the rack, wherein the first slot and the second slot are coupled together via a first interconnect; and
a test module that performs an in-system end-to-end signal integrity (SI) performance test of the first interconnect by:
transmitting a first test signal across the first interconnect via the first test blade,
receiving a second test signal from across the first interconnect via the second test blade, and
generating a SI performance analysis of the first interconnect based on the first test signal and the second test signal.

2. The diagnostic instrument of claim 1, wherein the first test blade includes a printed circuit board that compensates for timing mismatches between communication pathways included in the first interconnect.

3. The diagnostic instrument of claim 1, wherein the first test blade includes a printed circuit board that compensates for impedance mismatches between communication pathways included in the first interconnect.

4. The diagnostic instrument of claim 1, wherein the first test blade includes a plurality of length and impedance controlled printed circuit board traces that compensates for timing and impedance mismatches associated with a plurality of communication pathways included in the first interconnect.

5. The diagnostic instrument of claim 1, wherein then first interconnect resides in a backplane or midplane that comprises a printed circuit board assembly or a cable cartridge backplane or midplane.

6. The diagnostic instrument of claim 1, wherein the test module comprises a vector network analyzer, or a time-domain reflectometer, or a bit error rate tester.

7. The diagnostic instrument of claim 1, further comprising:
a computing device, including:
a processor, and
a memory storing program instructions that, when executed by the processor cause the processor to:
transmit the first test signal across the first interconnect via the first test blade,
receive the second test signal from across the first interconnect via the second test blade, and
generate the SI performance analysis of the first interconnect based on the first test signal and the second test signal.

8. The diagnostic instrument of claim 1, wherein each of the first test blade and the second test blade has a form factor that is substantially similar to a regular blade.

9. The diagnostic instrument of claim 1, wherein the SI performance analysis quantifies at least one packet loss, error rate, or signal attenuation.

10. The diagnostic instrument of claim 1, wherein the test module further performs the in-system end-to-end SI performance test of the first interconnect by:
transmitting a third test signal across the first interconnect via the second test blade, and
receiving a fourth test signal from across the first interconnect via the first test blade, wherein the SI performance analysis of the first interconnect is further generated based on the third test signal and the fourth test signal.

11. A system, comprising:
a rack, including:
a first slot,
a second slot, and
a backplane or midplane that includes a first interconnect coupling the first slot to the second slot;
a first test blade coupled to the first slot;
a second test blade coupled to the second slot; and
a test module that performs an in-system end-to-end signal integrity (SI) performance test of the first interconnect by:
transmitting a first test signal across the first interconnect via the first test blade,
receiving a second test signal from across the first interconnect via the second test blade, and
generating a SI performance analysis of the first interconnect based on the first test signal and the second test signal.

12. The system of claim 11, wherein the first test blade includes a printed circuit board that compensates for timing mismatches between communication pathways included in the first interconnect.

13. The system of claim 11, wherein the first test blade includes a printed circuit board that compensates for impedance mismatches between communication pathways included in the first interconnect.

14. The system of claim 11, wherein the first test blade includes a plurality of length and impedance controlled printed circuit board traces that compensate for timing and impedance mismatches associated with a plurality of communication pathways included in the first interconnect.

15. The system of claim 11, wherein the backplane or midplane comprises a printed circuit board assembly or a cable cartridge backplane or midplane that includes a plurality of high-speed cables.

16. The system of claim 11, wherein the test module comprises a vector network analyzer (VNA), or a time-domain reflectometer (TDR), or a bit error rate tester (BERT).

17. The system of claim 11, further comprising:
a computing device, including:
a processor, and
a memory storing program instructions that, when executed by the processor, cause the processor to:
transmit the first test signal across the first interconnect via the first test blade,
receive the second test signal from across the first interconnect via the second test blade, and
generate the SI performance analysis of the first interconnect based on the first test signal and the second test signal.

18. The system of claim 11, wherein each of the first test blade and the second test blade has a form factor that is substantially similar to a regular blade.

19. The system of claim 11, wherein the test module performs a second in-system end-to-end SI performance test of a second interconnect by:
transmitting a third test signal across the second interconnect via the first test blade,
receiving a fourth test signal from across the second interconnect via the second test blade, and
generating a second SI performance analysis of the second interconnect based on the third test signal and the fourth test signal.

20. A test blade, comprising:
a circuit board, including:
a set of traces that couples the circuit board to a first interconnect included in a rack via a connector type that resides on a regular blade, and
an internal connector that is coupled to a first trace included in the set of traces; and
an external connector that couples the internal connector to a test module, wherein the test module generates a signal integrity (SI) performance analysis of the first interconnect by transmitting a first test signal across the first interconnect via the first trace.

21. The test blade of claim 20, wherein the first interconnect resides in a backplane or midplane included in the rack, and further comprising:
a backplane or midplane connector, including:
a first segment that couples the first trace to the first interconnect, wherein the first segment corresponds to a logical or a physical grouping associated with the backplane or midplane, and
a second segment that couples a second trace to the first interconnect, wherein the second segment corresponds to a different logical or a different physical grouping associated with the backplane or midplane.

22. The test blade of claim 20, wherein the internal connector comprises a land-grid array (LGA) connector or a SubMiniature version A (SMA) connector, wherein the internal connector is coupled to the external connector via a high-speed cable, wherein a mounting location of the internal to the first trace is adjustable based on the SI performance analysis, and wherein the test module is coupled to a failed first path during end-to-end SI performance testing and analysis from the first trace to the first interconnect and to a second trace on a second blade that is interconnected with the backplane in another slot.

23. The test blade of claim 20, wherein the set of traces compensates for timing and impedance mismatches associated with a plurality of communication pathways included in the first interconnect.

24. The test blade of claim 20, wherein the rack comprises a manufacturing tester or test rack and the backplane comprises a loopback printed circuit board.

25. A diagnostic instrument, comprising:
a first test blade coupled to a first slot in a rack, wherein the first slot is coupled to a first interconnect; and
a test module that performs an in-system end-to-end SI performance test of the first interconnect by:
transmitting a first test signal across the first interconnect via the first test blade, and
generating a SI performance analysis of the first interconnect based on the first test signal.

26. The diagnostic instrument of claim 25, wherein the first test blade includes a printed circuit board that compensates for timing mismatches between communication pathways included in the first interconnect.

27. The diagnostic instrument of claim 25, wherein the first test blade includes a printed circuit board that compensates for impedance mismatches between communication pathways included in the first interconnect.

28. The diagnostic instrument of claim 25, wherein the first test blade includes a plurality of length and impedance controlled printed circuit board traces that compensates for timing and impedance mismatches associated with a plurality of communication pathways included in the first interconnect.

29. The diagnostic instrument of claim 25, wherein then first interconnect resides in a backplane or midplane that comprises a printed circuit board assembly or a cable cartridge backplane or midplane.

30. The diagnostic instrument of claim 25, wherein the test module comprises a vector network analyzer, or a time-domain reflectometer, or a bit error rate tester.

31. The diagnostic instrument of claim 25, further comprising:
a computing device, including:
a processor, and
a memory storing program instructions that, when executed by the processor cause the processor to:
transmit the first test signal across the first interconnect via the first test blade, and
generate the SI performance analysis of the first interconnect based on the first test signal.

32. The diagnostic instrument of claim 25, wherein the first test blade has a form factor that is substantially similar to a regular blade.

33. The diagnostic instrument of claim 25, wherein the SI performance analysis quantifies at least one packet loss, error rate, or signal attenuation.
